(19) United States
(12) Patent Application Publication
(10) Pub. No.: US 2026/0101703 A1
(43) Pub. Date: Apr. 9, 2026

(54) SUBSTRATE PROCESSING APPARATUS AND SUBSTRATE TRANSFER APPARATUS

(71) Applicant: SEMES CO., LTD., Cheonan-si (KR)

(72) Inventors: Ki Won HAN, Anseong-si (KR); Doo Hyun BAEK, Hwaseong-si (KR); Hee Chan KIM, Hwaseong-si (KR); Sang Oh KIM, Seoul (KR)

(73) Assignee: SEMES CO., LTD., Cheonan-si (KR)

(21) Appl. No.: 19/348,376

(22) Filed: Oct. 2, 2025

(30) Foreign Application Priority Data
Oct. 7, 2024 (KR) 10-2024-0135990

(51) Int. Cl. H01L 21/67; B65G 47/90; H01L 21/687

(52) U.S. Cl. CPC H10P 72/0468; B65G 47/907; H10P 72/0456; H10P 72/7602; H10P 72/0458

(57) ABSTRACT

Disclosed is an apparatus for processing a substrate and an apparatus for transferring a substrate. The apparatus for processing the substrate includes: an index module including a load port on which a container containing a substrate is placed and an index robot that loads or unloads a substrate into or from the container placed on the load port; and a processing module for processing the substrate transferred from the container placed on the index module, in which the processing module includes: a buffer unit on which the substrate is placed temporarily; and a main transfer robot for transferring the substrate between the buffer unit and a processing chamber that processes the substrate, the index robot is provided to approach the buffer unit, and the buffer unit includes: a plurality of buffers which is stacked on each other and supports the substrate; and an interval changing unit for changing an interval between adjacent buffers among the buffers.

### CROSS-REFERENCE TO RELATED APPLICATION

This application claims priority to and the benefit of Korean Patent Application No. 10-2024-0135990 filed in the Korean Intellectual Property Office on Oct. 7, 2024, the entire contents of which are incorporated herein by reference.

### TECHNICAL FIELD

The present invention relates to a substrate processing apparatus and a substrate transfer apparatus, and more specifically, to a substrate processing apparatus and a substrate transfer apparatus capable of changing an interval between buffers provided to a buffer unit.

### BACKGROUND ART

The semiconductor process includes a process of cleaning thin films, foreign substances, particles, and the like on a substrate. Each process is performed in a substrate processing apparatus performing each process. The substrate processing apparatus includes an index module and a processing module. The index module includes an index robot in which a container (e.g., a Front Opening Unified Pod (FOUP)) containing a substrate to be processed is seated, and which transfers the substrate in the container to the processing module, and the processing module includes a buffer unit for temporarily storing a substrate, a main transfer robot for transferring the substrate, and a processing chamber for processing the substrate. The substrate to be processed is transferred to the buffer unit in the processing module by the robot in the index module. Further, the substrate is again transferred to the processing chamber by the robot in the processing module and processed in the processing chamber. That is, the index robot and the main transfer robot enter opposite sides of the buffer unit using the buffer unit as a medium for transferring the substrate, respectively.

In general, two robots use multiple hands stacked at regular intervals to increase substrate transfer efficiency. In order for a plurality of hands of each robot to simultaneously enter the buffer unit, the interval between adjacent hands needs to be the same as the interval between the buffers. That is, the interval between the hands of the index robot, the interval between the buffers, and the interval between the hands of the main transfer robot need to be maintained the same. However, since the hands of the index robot must enter the FOUP, the interval between the hands needs to match the interval between the substrate supports provided to the FOUP. As a result, the interval between the hands of the main transfer robot has to be adjusted to match the interval between the hands of the index robot.

However, in order to secure the high-speed movement and transfer stability of the transfer robot, the need to change the design and interval of the hands of the transfer robot has recently been raised. However, when the interval between the hands of the transfer robot is set differently from that of the index robot, there is a problem that the transfer robot fails to enter the buffer unit properly due to the reasons mentioned above, causing a disruption in transferring the substrate.

### SUMMARY OF THE INVENTION

The present invention has been made in an effort to provide a substrate processing apparatus and a substrate transfer apparatus capable of transferring a substrate even when an interval between a plurality of hands provided to an index robot and an interval between a plurality of hands provided to a main transfer robot are different from each other.

The present invention has also been made in an effort to provide a substrate processing apparatus and a substrate transfer apparatus capable of changing an interval between adjacent buffers.

The objectives of the present disclosure are not limited thereto and other objectives not stated herein may be clearly understood by those skilled in the art from the following description.

An exemplary embodiment of the present disclosure, an apparatus for processing a substrate, the apparatus comprising: an index module including a load port on which a container containing a substrate is placed and an index robot that loads or unloads a substrate into or from the container placed on the load port; and a processing module for processing the substrate transferred from the container placed on the index module, wherein the processing module includes: a buffer unit on which the substrate is placed temporarily; and a main transfer robot for transferring the substrate between the buffer unit and a processing chamber that processes the substrate, the index robot is provided to approach the buffer unit, and the buffer unit may includes: a plurality of buffers which is stacked on each other and supports the substrate; and an interval changing unit for changing an interval between adjacent buffers among the buffers.

According to the exemplary embodiment of the present invention, wherein the interval changing unit includes: a body having a plurality of support surfaces; and a driver for moving the body in a vertical direction, the plurality of support surfaces is provided to correspond to the plurality of buffers, respectively, and when the body is moved upward, one of the plurality of buffers may be moved upward by a corresponding support surface among the plurality of support surfaces.

According to the exemplary embodiment of the present invention, wherein each of the buffers has a groove penetrating in a vertical direction, and the body may be provided to be moved along the groove.

According to the exemplary embodiment of the present invention, wherein the plurality of support surfaces is provided to be stepped from each other such that the lower the plurality of support surfaces is positioned lower, the farther the plurality of support surfaces is from a center of the body, each of the plurality of buffers has a contact surface that is in contact with a corresponding support surface among the plurality of support surfaces, the contact surface is provided such that the higher the contact surface is positioned, the closer the contact surface is to a central axis of the body, and the support surface and the contact surface that correspond to each other may be provided such that the contact surface is positioned above the support surface.

According to the exemplary embodiment of the present invention, wherein a height difference between the support surfaces that are adjacent to each other among the plurality of support surfaces may be provided to be greater than a height difference between the contact surfaces that are adjacent to each other among the plurality of contact surfaces.

According to the exemplary embodiment of the present invention, wherein the buffer unit is position-changeable between a first state in which an interval between the adjacent buffers is maintained at a first interval and a second state in which an interval between the adjacent buffers is maintained at a second interval that is greater than the first interval, and when the body is disposed at a first height, the plurality of buffers is maintained in the first state, and when the body is at a second height higher than the first height, the plurality of buffers may be maintained in the second state.

According to the exemplary embodiment of the present invention, wherein when the plurality of buffers is in the first state and the body is at the first height, a gap between the support surface and the contact surface that correspond to each other among the plurality of support surfaces and the plurality of contact surfaces may be provided to be larger as the support surface and the contact surface are positioned lower.

According to the exemplary embodiment of the present invention, wherein as the body is moved from the first height to the second height, the contact surface positioned above among the plurality of contact surfaces first comes into contact with the corresponding support surface among the plurality of support surfaces and may moves.

According to the exemplary embodiment of the present invention, wherein the index robot includes a plurality of index hands stacked on each other, intervals between at least some of the plurality of index hands in the vertical direction are provided as a first interval, the main transfer robot includes a plurality of transfer hands stacked on each other, and intervals between at least some of the plurality of transfer hands in the vertical direction may be provided as a second interval.

According to the exemplary embodiment of the present invention, wherein the buffer positioned at the lowest among the plurality of buffers may be provided as a fixed buffer of which a position is fixed, and the remaining buffers are provided as moving buffers of which positions are moved by the driver.

According to the exemplary embodiment of the present invention, wherein each of the buffers includes: a body; and a support having a shape that protrudes and extends inward from the body, and supports a lower surface of the substrate, and the contact surface may be provided to the body.

According to the exemplary embodiment of the present invention, the apparatus may further include a controller, wherein the controller controls an interval changing unit to change the interval between adjacent buffers among the plurality of buffers to the first interval when the first robot approaches the buffer unit.

According to the exemplary embodiment of the present invention, wherein the controller may controls the interval changing unit to change the interval between adjacent buffers among the plurality of buffers to the second interval when the second robot approaches the buffer unit.

An exemplary embodiment of the present disclosure, an apparatus for transferring a substrate, the apparatus comprising: a first robot having a plurality of first hands on which a substrate is placed and which is provided to be spaced apart from each other in a vertical direction; a second robot having a plurality of second hands on which a substrate is placed and which is provided to be spaced apart from each other in the vertical direction; and a buffer unit having a plurality of buffers on which the substrate is placed and which is stacked in the vertical direction, each of the first robot and the second robot is provided to approach the buffer unit, at least some of the plurality of first hands are provided to have a first interval in the vertical direction, at least some of the plurality of second hands are provided to have a second interval in the vertical direction, and the buffer unit further may includes an interval changing unit for changing an interval between adjacent buffers among the plurality of buffers between the first interval and the second interval.

According to the exemplary embodiment of the present invention, wherein the interval changing unit includes: a body having a plurality of support surfaces; and a driver for moving the body between a first height and a second height higher than the first height, the buffers are provided in three or more, and all intervals between the adjacent buffers may be provided to be changeable by a lifting movement of the body.

According to the exemplary embodiment of the present invention, wherein when the body is at the first height, an interval between adjacent buffers among the plurality of buffers is the first interval, and when the body is at the second height, an interval between adjacent buffers among the plurality of buffers may be the second interval.

According to the exemplary embodiment of the present invention, wherein when the body rises from the first height to the second height, the buffer may be lifted from the buffer at the highest position among the plurality of buffers.

An apparatus for processing a substrate, the apparatus comprising: an index module including a load port on which a container containing a substrate is placed and an index robot that loads or unloads a substrate into or from the container placed on the load port; and a processing module for processing the substrate transferred from the container placed on the index module, wherein the processing module includes: a buffer unit on which the substrate is placed temporarily; and a main transfer robot for transferring the substrate between the buffer unit and a processing chamber that processes the substrate, the index robot is provided to approach the buffer unit, and the buffer unit is position-changeable between a first state in which an interval between the adjacent buffers is maintained at a first interval and a second state in which an interval between the adjacent buffers is maintained at a second interval that is greater than the first interval, the buffer unit includes: a plurality of buffers that is stacked on each other and supports the substrate; and an interval changing unit for changing an interval between the adjacent buffers among the buffers, the interval changing unit includes: a body having a plurality of support surfaces; and a driver for moving the body in a vertical direction, the plurality of support surfaces is provided to correspond to the plurality of buffers, respectively, and the plurality of support surfaces is provided to be stepped from each other such that the lower the plurality of support surfaces is positioned, the farther the plurality of support surfaces is from a center of the body, each of the plurality of buffers has a contact surface that is in contact with a corresponding support surface among the plurality of support surfaces, the support surface and the contact surface that correspond to each other are provided such that the contact surface is positioned above the support surface, the plurality of contact surfaces is provided such that the higher the contact surface is positioned, the closer the contact surface is to a central axis of the body, a height difference between the support surfaces adjacent to each other among the plurality of support surfaces is provided to be greater than a height difference between the contact surfaces adjacent to each other among the plurality of contact surfaces, the driver is provided to be able to move the body vertically between a first height and a second height higher than the first height, the first height is a height at which an interval between the adjacent buffers is the first interval, the second height is a height at which an interval between the adjacent buffers is the second interval when the support surface and the contact surface that correspond to each other are in contact with each other, the index robot includes a plurality of index hands stacked on each other, intervals between at least some of the plurality of index hands in a vertical direction is provided as the first interval, the main transfer robot includes a plurality of transfer hands stacked on each other, and intervals between at least some of the plurality of transfer hands in the vertical direction may be provided as the second interval.

According to the exemplary embodiment of the present invention, the apparatus may further include a controller, the controller controls the interval changing unit so that the buffer unit is changed to the first state when the index robot approaches the buffer unit, and may controls the interval changing unit so that the buffer unit is changed to the second state when the main transfer robot approaches the buffer unit.

According to the exemplary embodiment of the present invention, wherein the interval changing unit further may includes a body guide that guides vertical movement of the body, and the buffer unit further includes a buffer guide that has a longitudinal direction in the vertical direction and guides vertical movement of the plurality of buffers.

According to the exemplary embodiment of the present invention, it is possible to transfer a substrate even when an interval between a plurality of hands provided to an index robot and an interval between a plurality of hands provided to a main transfer robot are different from each other.

According to the exemplary embodiment of the present invention, it is possible to change an interval between adjacent buffers.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a top plan view schematically illustrating a substrate processing apparatus according to an exemplary embodiment of the present invention.

FIG. 2 is a diagram schematically illustrating an exemplary embodiment of a liquid processing chamber of FIG. 1.

FIG. 3 is a side view of an index robot of FIG. 1.

FIG. 4 is a diagram illustrating a substrate guide provided to a main transfer robot of FIG. 1.

FIG. 5 is a side view of the main transfer robot of FIG. 1.

FIG. 6 is a diagram schematically illustrating a plurality of buffers and a driving member of the buffer unit of FIG. 1.

FIG. 7 is a diagram illustrating a state in which the plurality of buffers and the driving member are viewed from the outside of the buffer unit in a second direction in a first state.

FIGS. 8 and 9 are diagrams sequentially illustrating a process in which the buffer unit changes from the first state to the second state.

FIG. 10 is a diagram illustrating a state in which the plurality of buffers and the driving member are viewed from the outside of the buffer unit in a second direction in a second state.

FIG. 11 is a diagram illustrating a process of transferring a substrate from the index robot to a buffer robot.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer is described as an example as an object to be processed. However, the technical idea of the present invention may be applied to devices used for processing other types of substrates other than wafers as objects to be processed.

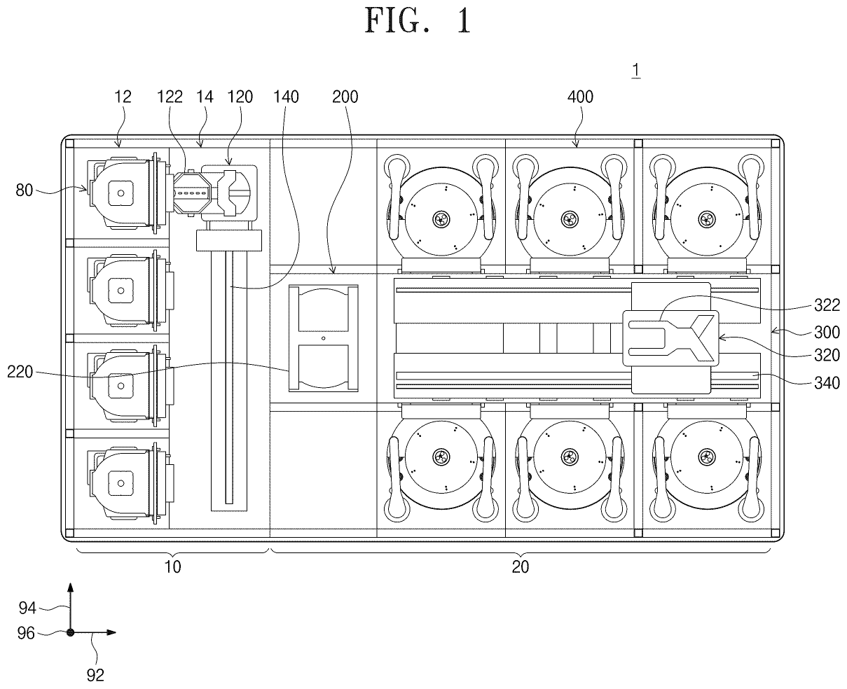

Hereinafter, an exemplary embodiment of the present invention will be described with reference to the accompanying drawings. FIG. 1 is a top plan view schematically illustrating a substrate processing apparatus according to an exemplary embodiment of the present invention.

Referring to FIG. 1, a substrate processing apparatus of the present invention includes a plurality of modules. According to an example, the substrate processing apparatus of the present invention may include a first module and a second module. The first module and the second module are provided adjacent to each other. The first module and the second module perform separate functions.

Each of the first module and the second module has a robot for transferring a substrate. Also, the second module includes a buffer unit. The robots of the first module and the second module are provided to be approachable to a buffer unit. The first module and the second module may exchange substrates with each other via a buffer unit. In the substrate processing apparatus described below, a module having a robot for transferring a substrate may be the first module, and a module having a robot for transferring a substrate and a buffer unit may be the second module. For example, the first module may be an index module 10 and the second module may be a processing module 20. The substrate processing apparatus includes the index module 10, the processing module 20, and a controller 30. According to the exemplary embodiment, the index module 10 and the processing module 20 are disposed along one direction. Hereinafter, the direction in which the index module 10 and the processing module 20 are disposed is referred to as a first direction 92, and when viewed from above, a direction perpendicular to the first direction 92 is referred to as a second direction 94, and a direction perpendicular to both the first direction 92 and the second direction 94 is referred to as a third direction 96. Furthermore, each of the first direction 92, the second direction 94, and the third direction 96 includes a direction opposite thereto. According to an example, the first direction 92 includes not only a direction in which the index module 10 and the processing module 20 are arranged, but also a reverse direction thereof. The first direction 92 may be referred to as the front-rear direction, the second direction 94 may be referred to as the left-right direction, and the third direction 96 may be referred to as the up-down direction.

The index module 10 transfers a substrate W from a container 80 in which the substrate W is accommodated to the processing module 20, and makes the substrate W, which has been completely processed in the processing module 20, be accommodated in the container 80. A longitudinal direction of the index module 10 is provided in the second direction 94. The index module 10 includes a load port 12 and an index frame 14. Based on the index frame 14, the load port 12 is located at a side opposite to the processing module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 of which a longitudinal direction is the second direction 94 is provided within the index frame 14, and the index robot 120 may be provided to be movable on the guide rail 140. The index robot 120 includes a hand 122 on which the substrate W is placed, and the hand 122 may be provided to be movable forward and backward, rotatable about the third direction 96, and movable along the third direction 96.

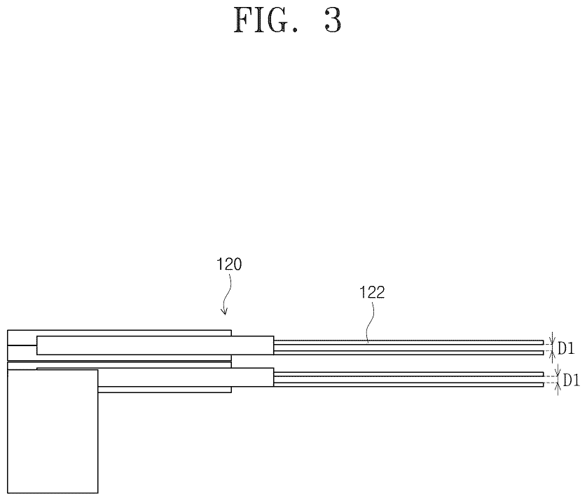

FIG. 3 is a side view of an index robot of FIG. 1. Referring to FIG. 3, a plurality of index hands 122 is provided to be spaced apart from each other in the vertical direction. At least some of the index hands 122 are provided at a first interval D1 in the vertical direction. According to an example, the first interval may be 10 mm. Further, according to an example, four index hands 122 are provided, each two index hands form a pair, and the index hands 122 in one pair are provided to have the first interval D1. The index hands 122 of each pair may be provided to have an interval different from the first interval D1. Hereinafter, it will be assumed that “the interval between the index hands 122 adjacent to each other” means the interval between the index hands 122 provided in the same pair. One pair of index hands 122 may simultaneously enter the buffer unit 200. One pair of index hands 122 may be used to transfer the substrate W before being processed, and the other pair of index hands 122 may be used to transfer the substrate W after being processed. However, the present invention is not limited thereto, and the plurality of index hands 122 may be provided in various combinations. In addition, each index hand 122 is provided to move forward and backward independently of each other.

The processing module 20 includes a buffer unit 200, a transfer chamber 300, and a processing chamber 400. The buffer unit 200 provides a space in which the substrate W loaded into the processing module 20 and the substrate W unloaded from the processing module 20 stay temporarily. The processing chamber 400 performs a processing process of liquid-processing the substrate W by supplying a liquid onto the substrate W. The transfer chamber 300 transfers the substrate W between the buffer unit 200 and the liquid processing chamber 400.

The transfer chamber 300 may be provided so that a longitudinal direction is the first direction 92. The buffer unit 200 may be disposed between the index module 10 and the transfer chamber 300. A plurality of liquid processing chambers 400 is provided and may be disposed on the side of the transfer chamber 300. The liquid processing chamber 400 and the transfer chamber 300 may be disposed in the second direction 94. The buffer unit 200 may be located at one end of the transfer chamber 300.

According to the example, the liquid processing chambers 400 are respectively disposed on opposite sides of the transfer chamber 300. At each of opposite sides of the transfer chamber 300, the liquid processing chambers 400 may be provided in an array of A×B (each of A and B is 1 or a natural number greater than 1) in the first direction 92 and the third direction 96.

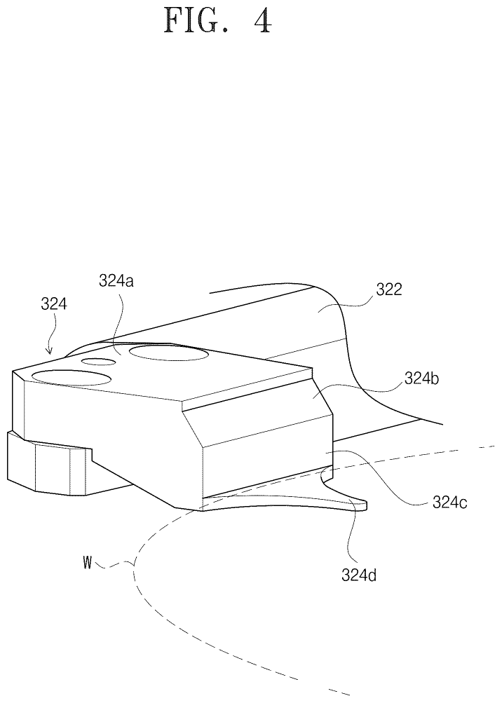

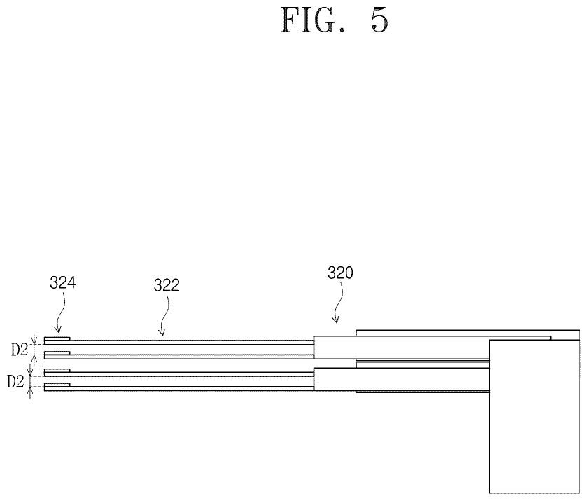

FIG. 4 is a diagram illustrating a substrate guide provided to a main transfer robot of FIG. 1, and FIG. 5 is a side view of the main transfer robot of FIG. 1. Referring to FIGS. 4 and 5, the transfer chamber 300 includes a main transfer robot 320. A guide rail 340 having a longitudinal direction in the first direction 92 is provided in the transfer chamber 300, and the main transfer robot 320 may be provided to be movable on the guide rail 340. The main transfer robot 320 includes a transfer hand 322 in which the substrate W is placed, and the transfer hand 322 may be provided to be movable forward and backward, rotatable about the third direction 96, and movable along the third direction 96.

A substrate guide 324 may be provided at the transfer hand 322. The substrate guide 324 has a structure in which the transfer hand 322 may stably hold and transfer the substrate W. According to an exemplary embodiment, the substrate guide 324 includes a coupling portion 324a, a guide wall 324b, a support wall 324c, and a seating surface 324d.

The coupling portion 324a allows the substrate guide 324 to be coupled to the hand 322. According to an example, the coupling portion 324a may be coupled to the hand 322 by a bolt.

The guide wall 324b is provided as a wall inclined downward toward the inside of the hand 322. The guide wall 324b may be a wall extending in a downwardly inclined direction from the coupling portion 324a. The guide wall 324b guides the substrate W to the seating surface 324d. Furthermore, the guide wall 324b allows the substrate W, which is misplaced, to be stably gripped. The substrate guide 324 may stably grip the substrate W according to the inclination and length of the guide wall 324b. However, as the guide wall 324b is provided, the thickness of the substrate guide 324 becomes thicker, which may cause an increase in an interval between adjacent transfer hands 322.

The support wall 324c has a shape extending in the vertical direction from the guide wall 324b. The support wall 324c prevents the position of the substrate W supported by the seating surface 324d from being misaligned. The support wall 324c fixes the position of the substrate W by being in contact with the substrate W at the side portion of the substrate W.

The seating surface 324d allows the substrate W guided by the guide wall 324b to be seated. The seating surface 324d has a phenomenon extending inward from a lower end of the support wall 324c. Accordingly, the seating surface 324d supports a lower surface of the substrate W. Also, a plurality of substrate guides 324 may be provided. According to an example, four substrate guides 324 may be provided and may be disposed to support the substrate W in four directions. By supporting the lower surface of the substrate W with the seating surface 324d and fixing the side of the substrate W with the support wall 324c in the four directions at the same time, even when the main transfer robot 320 moves at high speed, distortion of the substrate W may be suppressed and stably transferred.

In addition, a plurality of transfer hands 322 is provided to be spaced apart in the vertical direction. At least some of the transfer hands 322 are provided at a second interval D2 in the vertical direction. According to an example, the second interval may be 15 mm. Further, according to an example, four transfer hands 322 are provided and two transfer hands 322 forms one pair, and the pair of transfer hands 322 are provided to have the second interval D2 between the transfer hands 322 of one pair. Each pair of transfer hands 322 may be provided to have an interval different from the second interval D2. Hereinafter, it will be assumed that “the interval between the transfer hands 322 adjacent to each other” means the interval between the transfer hands 322 provided in the same pair. A pair of transfer hands 322 may simultaneously enter the buffer unit 200. A pair of transfer hands 322 may be used to transfer the substrate W before being processed, and the other pair of transfer hands 322 may be used to transfer the substrate W after being processed. However, the present invention is not limited thereto, and a plurality of transfer hands 322 may be provided in various combinations. In addition, each of the transfer hands 322 is provided to move forward and backward independently of each other.

In the above-described example, the present invention has been described based on the case where as the substrate guide 324 is provided, the interval between the adjacent transfer hands 322 is provided larger than the interval between the adjacent index hands as an example. However, the present invention is not limited thereto, and the interval between the adjacent transfer hands 322 may be provided larger than the interval between the adjacent index hands due to another configuration or purpose.

The buffer unit 200 includes a plurality of buffers 220 on which the substrate W is temporarily placed. The buffers 220 may be disposed while being spaced apart from each other in the third direction 96. A front face and a rear face of the buffer unit 200 are opened. The front face is a face facing the index module 10, and the rear face is a face facing the transfer chamber 300. The index robot 120 may approach the buffer unit 200 through the front face, and the main transfer robot 320 may approach the buffer unit 200 through the rear face. Details of the buffer unit 200 will be described later.

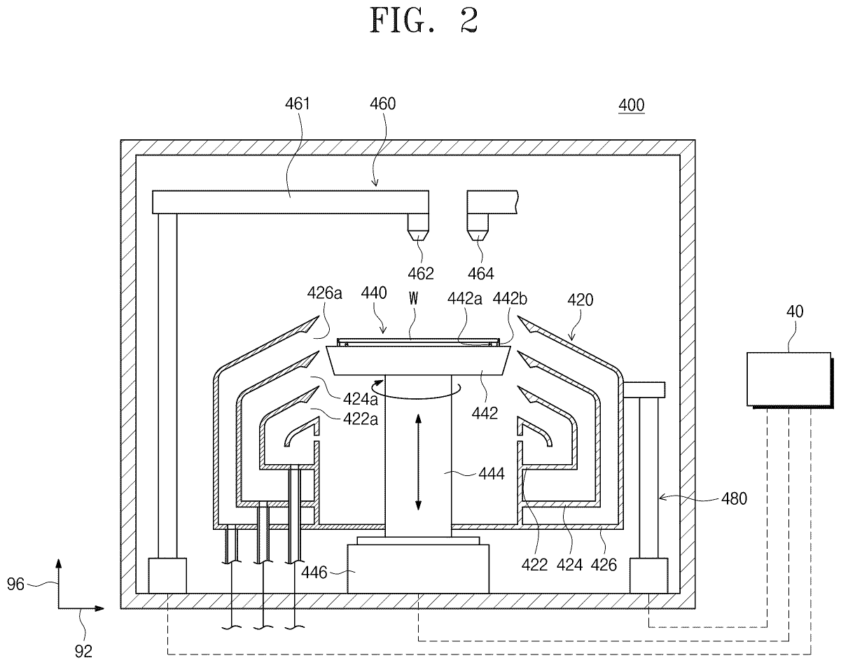

FIG. 2 is a diagram schematically illustrating the liquid processing chamber 400 of FIG. 1 according to the exemplary embodiment. Referring to FIG. 2, the liquid processing chamber 400 includes a housing 410, a cup body 420, a support unit 440, a nozzle unit 460, a lifting unit 450, a supply unit 460, and a controller.

The housing 410 is provided in a generally rectangular parallelepiped shape. The cup body 420, the support unit 430, and the nozzle unit 440 are disposed within the housing 410.

The cup body 420 has a processing space with an open top, and the substrate W is liquid-processed in the processing space. The support unit 430 supports the substrate W in the processing space. The nozzle unit 440 supplies the liquid to the substrate W supported by the support unit 430. The liquid may be provided in a plurality of types, and may be sequentially supplied onto the substrate W. The lifting unit 450 adjusts a relative height between the cup body 420 and the support unit 430.

According to an example, the cup body 420 includes a plurality of recovery containers 422, 424, and 426. Each of the recovery containers 422, 424, and 426 has a recovery space of recovering the liquid used for the processing of the substrate. Each of the recovery containers 422, 424, and 426 is provided in a ring shape surrounding the support unit 430. As the liquid processing process proceeds, the processing liquid scattered by the rotation of the substrate W is introduced into the recovery space through the inlets 422a, 424a, and 426a of the respective recovery containers 422, 424, and 426. According to the example, the cup body 420 includes a first recovery container 422, a second recovery container 424, and a third recovery container 426. The first recovery container 422 is disposed to surround the support unit 430, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 430 includes a support plate 432 and a drive shaft 434. An upper surface of the support plate 432 may be provided in a generally circular shape, and may have a diameter larger than a diameter of the substrate W. Further, a support pin 432a supporting the rear surface of the substrate W is provided at the center of the support plate 432, and the upper end of the support pin 432a is provided to protrude from the support plate 432 so that the substrate W is spaced apart from the support plate 432 by a predetermined distance. A chuck pin 432b is provided at an edge of the support plate 432. The chuck pin 432b is provided to protrude upward from the support plate 432, and supports the side portion of the substrate W so that the substrate W does not deviate from the support unit 430 when the substrate W is rotated. The drive shaft 434 is driven by the driver 436, is connected to the center of the bottom surface of the substrate W, and rotates the support plate 432 about its central axis.

The nozzle unit 440 includes a first nozzle 442 and a second nozzle 444. The first nozzle 442 supplies the processing liquid onto the substrate W. The second nozzle 444 supplies a processing liquid different from the processing liquid supplied by the first nozzle 442 onto the substrate W. The first nozzle 442 and the second nozzle 444 are supported by different arms 441, respectively, and these arms 441 may be moved independently. Optionally, the first nozzle 442 and the second nozzle 444 may be mounted on the same arm and moved at the same time.

Optionally, the liquid supply unit may further include one or more nozzles in addition to the first nozzle 442 and the second nozzle 444. The added nozzle may supply another type of processing liquid to the substrate. For example, another type of processing liquid may be an acid solution or a base solution for removing foreign substances on the substrate. In addition, another type of processing liquid may be alcohol having surface tension lower than water. For example, the alcohol may be isopropyl alcohol.

The lifting unit 450 moves the cup body 420 in the up and down direction. By the up and down movement of the cup body 420, a relative height between the cup body 420 and the substrate W is changed. Accordingly, the recovery containers 422, 424, and 426 for recovering the processing liquid are changed according to the type of liquid supplied to the substrate W, and thus the liquids may be separated and recovered. Unlike the description, the cup body 420 is fixedly installed, and the lifting unit 450 may move the support unit 430 in the vertical direction.

The supply unit 460 supplies the processing liquid to the nozzle unit 440. The supply unit 460 may include a plurality of processing liquid supply sources, which are not illustrated. In addition, the supply unit 460 may include a processing liquid supply line connecting a plurality of processing liquid sources and the nozzle unit 440. A valve, a pump, a filter, a heater, and the like may be installed in the processing liquid supply line.

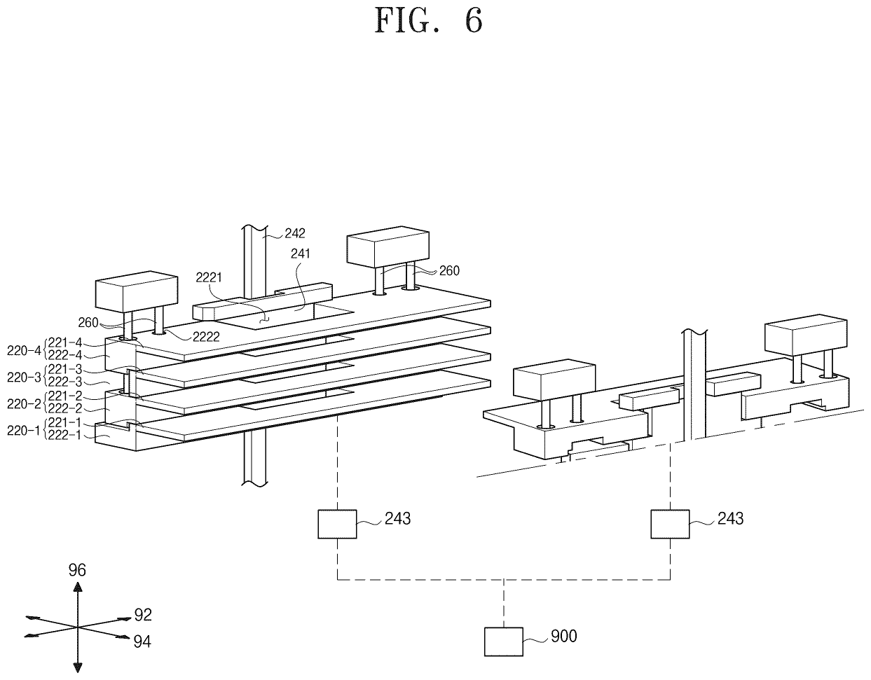

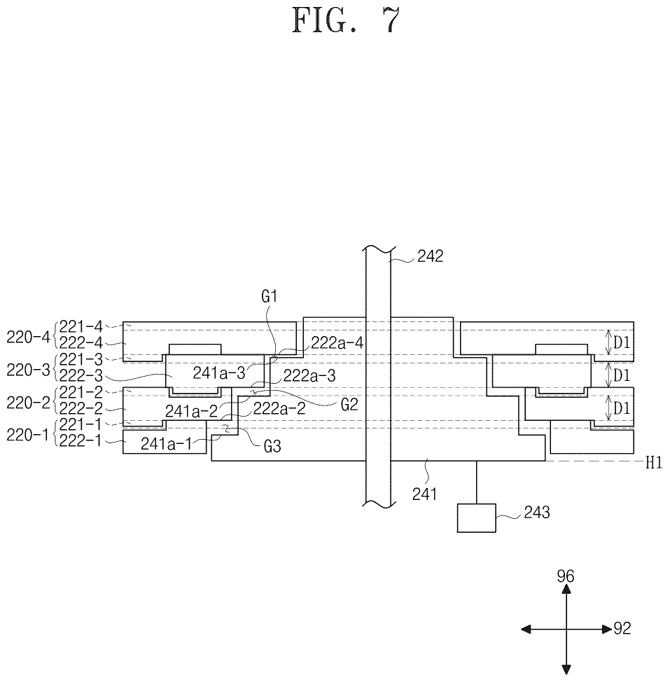

FIG. 6 is a diagram schematically illustrating a plurality of buffers and an interval changing unit provided in the buffer unit, and FIG. 7 is a view illustrating the buffer and the interval changing unit viewed from behind. Referring to FIGS. 6 and 7, the buffer unit 200 includes a plurality of buffers 220, an interval changing unit 240, and a buffer guide 260.

A plurality of buffers 220 are provided to support a plurality of substrates W. A plurality of buffers 220 are provided by being stacked on each other. The buffer 220 includes a fixed buffer and a moving buffer. The fixed buffer refers to the lowermost buffer among the plurality of buffers 220. The height of the fixed buffer is fixed. The moving buffer refers to the remaining buffers except for the fixed buffer among a plurality of buffers. The moving buffer may be moved by a driver 243 to be described later. According to an example, four buffers 220-1, 220-2, 220-3, and 220-4 are provided, and may consist of one fixed buffer 220-1 and three moving buffers 220-2, 220-3, and 220-4.

Each of the buffers 220 may include a support plate 221 and a body 222. The support plate 221 is provided in a plate shape having a longitudinal direction in the first direction 92. The lengths of the support plates 221 in the first direction 92 are provided to be the same. Also, the widths of the support plates 221 in the second direction 94 are provided to be the same. The support plate 221 is supported by the body 222. The support plate 221 has a shape protruding inward from the body 222. According to an example, the support plate 221 may be provided to have a shape protruding inward from an upper end of the body 222. In addition, the support plate 221 and the body 222 may be provided integrally. In FIG. 7, the support plate 221 is indicated by a dotted line.

The body 222 has a longitudinal direction in the first direction 92. Each body 222 is provided in a structure stacked on each other. When viewed from above, the respective bodies 222 are arranged to overlap each other. In addition, the body 222 is provided in a shape thicker than the support plate 221. According to an example, the body 222 may be provided in a shape extending downward based on a height at which the support plate 221 is provided. The thickness of each body 222 is provided to determine an interval between adjacent support plates 221 while each body 222 is in contact with each other. According to an example, the thickness of the body 222 may be set so that the interval between the adjacent support plates 221 becomes 10 mm.

Furthermore, the body 222 is provided to be movable in the vertical direction. The support plate 221 is also moved by the movement of the body 222. The body 222 includes an insertion groove 2221 and a through hole 2222.

The insertion groove 2221 may be formed at a central rear surface of the body. The insertion groove 2221 may be provided in a shape of which a rear surface is open. Also, the insertion groove 2221 may be provided in a shape that penetrates the body 222 in the third direction 96. The width of the insertion groove 2221 in the second direction 94 may be provided as a width by which the body 241 and the body guide 242 to be described later may be inserted. If necessary, the width of the insertion groove 2221 in the second direction 94 may extend to a region where the support plate 221 is provided.

The through hole 2222 may be formed in a hole shape penetrating the body 222 in the third direction 96. A plurality of through holes 2222 may be provided. The through holes 2222 may be arranged along the first direction 92. The through holes 2222 may be symmetrically arranged on opposite sides of the body 222. The diameter of the through hole 2222 is provided so that the buffer guide 260 may be inserted. The body 222 may be moved in the third direction by the body 241 and the body 242 located in the insertion groove 2221, and the buffer guide 260 inserted into the through hole 2222.

A contact surface 222a is provided on the lower surface of each body 222. The contact surface 222a is a surface that is in contact with the support surface 241a when the body 241 described later ascends. Each contact surface 222a has a corresponding support surface 241a. Each contact surface 222a needs to be in contact with a corresponding support surface 241a. Accordingly, each contact surface 222a is provided at a position at which a distance from a central axis of the body 241 is shorter as a contact surface of the buffer 220 is located higher. A specific correspondence relationship between the contact surface 222a and the support surface 241a will be described later. The specific shape of the body 222 may be determined in consideration of support stability of the substrate W, stacking stability between the bodies 222, performance of the driver 243 to be described later, and whether the body 22 is in contact with the body 241.

Each of the buffers 220 is provided in a symmetrical shape to support opposite sides of the lower surface of the substrate W. Accordingly, the support plate 221, the body 222, and the configurations formed therein may be provided in pairs in one buffer 220.

The interval changing unit 240 is provided to adjust the interval between the support plates 221 adjacent to each other. The interval changing unit 240 is provided to allow the plurality of buffers 220 to be switched between the first state and the second state. The first state refers to the state where the interval between the support plates 221 adjacent to each other is the first interval D1, and the second state refers to the state where the interval between the support plates 221 adjacent to each other is the second interval D2. The interval changing unit 240 includes the body 241, the body guide 242, and the driver 243.

The body 241 is provided in a stepped shape. The body 241 is provided in a shape in which the width of each stage increases as it goes down. In addition, each stage may be formed to have a width and length that may be inserted into a corresponding insertion groove 2221. According to an example, the body 241 is composed of four stages, and may be provided in a shape in which the length in the first direction 92 of each stage increases as it goes down to the lower stage.

The upper surface of each stage of the body 241 is provided as the support surface 241a. Each support surface 241a is provided so as to move away from the center of the body 241 as it goes downward. Each support surface 241a is provided to have the contact surface 222a of each corresponding buffer 220, and is provided below the corresponding contact surface 222a. According to an example, four buffers 220 are provided, the body 241 is formed in four stages, and if the stage is named as a first stage from below, the contact surface 222a-2 of the second-stage buffer 220-2 corresponds to the support surface 241a-1 of the first stage of the body 241, the contact surface 222a-3 of the third-stage buffer 220-3 corresponds to the support surface 241a-2 of the second stage of the body 241, and the contact surface 222a-4 of the fourth-stage buffer 220-4 may be provided to correspond to the support surface 241a-3 of the third stage of the body 241. The body 241 is provided to be movable in the vertical direction by the driver 243. Here, ‘corresponding’ means that the components are provided at positions facing each other, and at least a portion thereof is provided to overlap when viewed from above.

Furthermore, a height difference between the support surfaces 241a adjacent to each other may be provided at the second interval D2. Accordingly, in a state in which the support surfaces 241a and the adjacent contact surfaces 222s are in contact with each other, the interval between the support plates 221 adjacent to each other may be formed at the second interval D2.

The body guide 242 has the longitudinal direction in the vertical direction. The body guide 242 guides the movement of the body 241 in the vertical direction. The body guide 242 may be provided to be inserted into the insertion groove 2221 together with the body 241. Accordingly, the body 241 may be vertically moved in the insertion groove 2221.

The driver 243 provides power for moving the body 241 in the vertical direction. The driver 243 may be a motor or an actuator. However, the present invention is not limited thereto, and any means capable of providing power to the body 241 may be sufficient. The driver 243 is provided to move the body 241 between a first height H1 and a second height H2.

The first height H1 is a height at which the body 241 is lowered. At the first height H1, the buffer unit 200 is in the first state. The interval between the support plates 221 adjacent to each other in the first state may be provided as the first distance D1. Further, in the first state, the support surfaces 241a and the contact surfaces 222a adjacent to each other are spaced apart from each other and have a gap G therebetween. The size of the first gap G1 provided at the highest position may be a difference between the first interval D1 and the second interval D2. According to an example, the size of the first gap G1 may be 5 mm. The gap G may be provided to be larger as the gap G is formed at a lower position. The first height H1 may be a height that has an integer multiple of the size of the gap G formed at the highest position as the gap G is formed at the lower position. According to an example, the size of the second gap G2 may be 10 mm, and the size of the third gap G3 may be 15 mm. However, the present invention is not limited thereto, and the body 241 may further descend such that the second gap G2 and a third gap G3 may not be an integer multiple of the first gap G1.

The second height H2 is a height at which the body 241 is raised. At the second height H2, the body 241 lifts the buffer 220. Accordingly, at the second height H2, the plurality of buffers 220 is placed in the second state. In the second state, the interval between the support plates 221 adjacent to each other may be provided as the second interval D2.

The buffer guide 260 is provided in a rod shape having a longitudinal direction in the vertical direction. The buffer guide 260 is inserted into the through holes 2222 formed in each of the plurality of buffers 220, and guides the vertical movement of each buffer 220. The buffer guide 260 is provided in the number corresponding to the number of through holes 2222. A plurality of buffer guides 260 may be provided.

Two interval changing units 240 and two buffer guides 260 are provided, respectively. One interval changing unit 240 and one buffer guide 260 are provided to drive the support plate 221 and the body 222 provided at one side, and the other interval changing unit 240 and the other buffer guide 260 are provided to drive the support plate 221 and the body 222 provided at the other side.

The drivers 243 provided on opposite sides are provided to be driven in synchronization with each other. Accordingly, the support plate 221 and the body 222 provided on both sides may always be driven in the vertical direction at the same height. The control of the driver 243 may be performed by the controller 900.

The controller 900 may control the overall operation of the interval changing unit 240. The controller 900 may allow the buffer unit 200 to become the first state when the index robot 120 approaches the buffer unit 200, and may allow the buffer unit 200 to become the second state when the main transfer robot 320 approaches the buffer unit 200.

The controller 900 may include a Central Processing Unit (CPU), a Read Only Memory (ROM), and a Random Access Memory (RAM). The CPU executes the transfer processing of the substrate according to the transfer recipe of the substrate stored in their memory areas. In the transfer recipe of the substrate, control information of the device according to the transfer path of the substrate is input. Meanwhile, the recipe indicating such transfer control may be stored in a non-transitory computer-readable medium. The non-transitory computer-readable medium refers to a medium that stores data semi-permanently and is readable by a computer, rather than a medium that stores data for a short moment, such as a register, cache, and memory. Specifically, the above-described various applications or programs may be stored and provided on a non-transitory readable medium, such as a CD, DVD, hard disk, Blu-ray disk, USB, memory card, or ROM.

Hereinafter, a process in which the buffer unit 200 changes from the first state to the second state by controlling the interval changing unit 240 by the controller 900 will be described by referring to reference numerals illustrated in FIGS. 1 to 7. The process of changing from the second state to the first state is in the reverse order of the above process, and thus the description thereof is omitted.

Referring back to FIG. 7, the first state is a state in which the support surfaces 241a and the contact surfaces 222a adjacent to each other are spaced apart, and the respective bodies 222 are in contact with each other. The interval between the support plates 221 adjacent to each other in the first state is provided as the first interval D1. According to an example, the first interval D1 may be 10 mm. The interval between the index hands 122 adjacent to each other is also provided as the first interval D1. Accordingly, the plurality of hands 122 of the index robot 120 may enter each buffer 220.

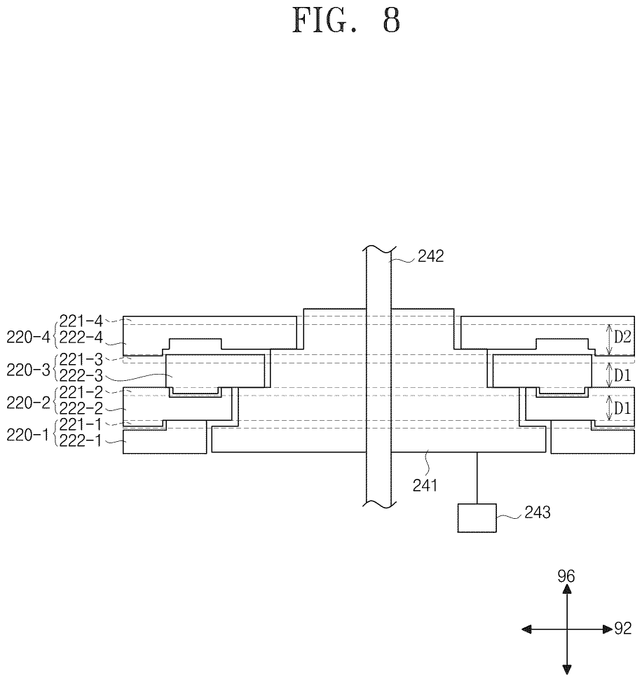

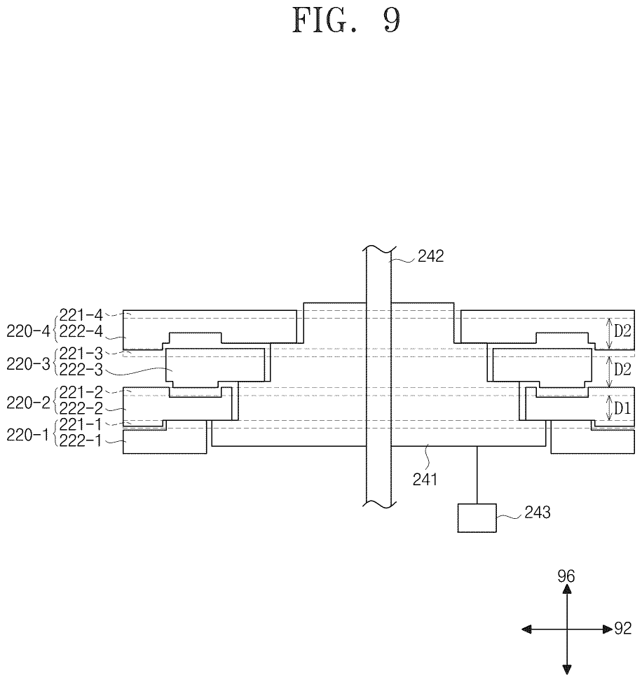

FIGS. 8 and 9 are diagrams sequentially illustrating a process in which the buffer unit changes from the first state to the second state. Referring to FIGS. 8 and 9, the body 241 ascends along the body guide 242 by the driver 243. As the body 241 ascends, first, the contact surface 222a-4 and the support surface 241a-3 are in contact with each other. Thereafter, as the body 241 further ascends, the support surface 241a-3 lifts the contact surface 222a-4, and the buffer 220-4 ascends. When the body 241 further ascends, the contact surface 222a-3 and the support surface 241a-2 come into contact with each other. In this case, the interval between the support plate 221-4 and the support plate 221-3 becomes the second interval D2.

The above process is repeated as the body 241 further ascends toward the second height H2. As the body 241 further ascends, the support surface 241a-2 lifts the contact surface 222a-3, and the buffer 220-3 ascends. When the body 241 further ascends, the contact surface 222a-2 and the support surface 241a-1 come into contact with each other. In this case, the interval between the support plate 221-3 and the support plate 221-2 also becomes the second interval D2.

As the body 241 further ascends, the support surface 241a-1 lifts the contact surface 222a-2, and the buffer 220-2 ascends. When the body 241 further ascends, the contact surface 222a-2 and the support surface 241a-1 come into contact with each other. Thereafter, the body 241 ascends until the distance between the support plate 221-2 and the support plate 221-1 becomes the second interval D2. The body 241 ascends up to the second height H2 in which the interval between the support plate 221-2 and the support plate 221-1 becomes the second interval D2. When the body 241 is located at the second height H2, the transition of the buffer unit 200 from the first state to the second state is completed.

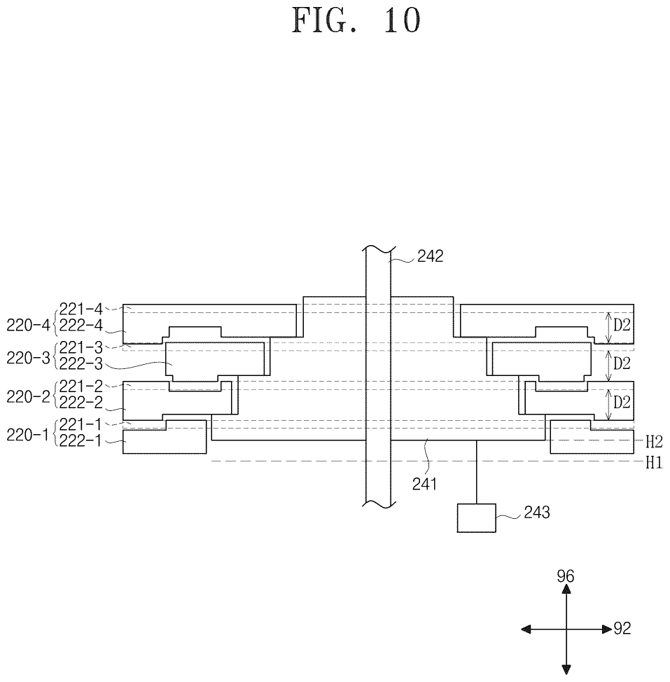

FIG. 10 is a diagram illustrating a state in which the plurality of buffers and the driving member are viewed from the outside of the buffer unit in the second direction in the second state. Referring to FIG. 10, an interval between the support plates 221 adjacent to each other in the second state is provided at the second interval D2. Since the hands 322 of the main transfer robots adjacent to each other are provided at the second interval D2, the hands 322 of the main transfer robot may enter the buffer 220.

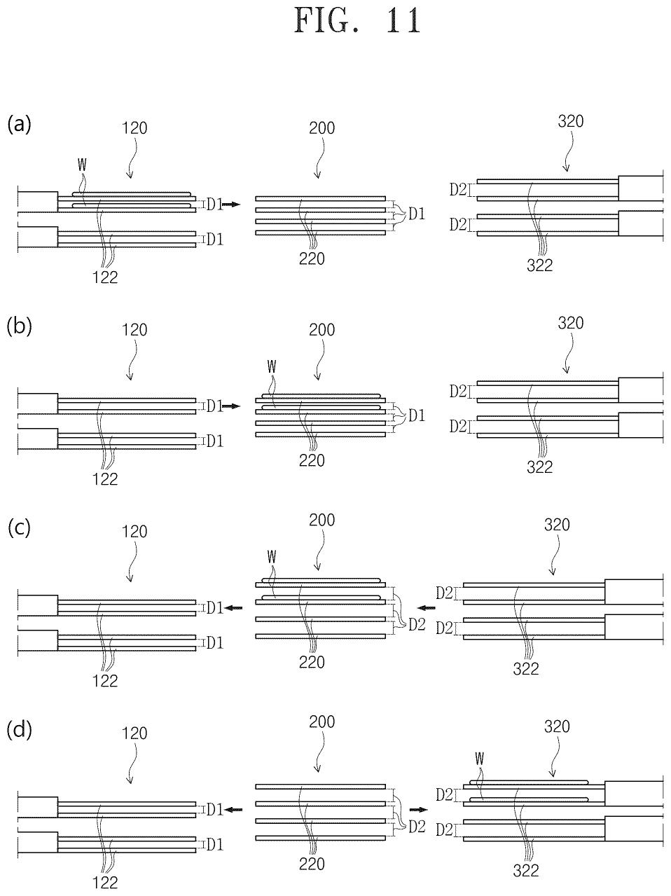

FIG. 11 is a diagram illustrating a process of transferring a substrate from the index robot to the buffer robot. Referring to FIG. 11, the index robot 120 may grip the substrate W from the container, and may approach the buffer unit 200. The buffer unit 200 may be in the first state. An interval between adjacent buffers 220 may be controlled to have the first interval D1 ((a) of FIG. 11). The index hands 122 simultaneously enter the buffers 220, respectively, and may transfer the substrate W to each buffer 220. Since the interval between the index hands 122 adjacent to each other is provided at the first interval D1, the index hands 122 may easily enter the buffers 220, respectively ((b) of FIG. 11). Thereafter, the main transfer robot 320 approaches the buffer unit 200. The buffer unit 200 is controlled to be in the second state. The interval between adjacent buffers 220 is changed to the second interval D2. The change from the first state to the second state may be achieved by the interval changing unit 240 as described above ((c) of FIG. 11). When the conversion to the second state is completed, the main transfer robot 320 enters the buffer unit 200 to grip the substrate W, and unloads the substrate W from the buffer unit 200. Even when the interval between adjacent transfer hands 322 is provided to have the second interval D2 different from the first interval D1, the transfer hands 322 may be easily entered into the buffers 220, respectively, because the interval between the buffers 220 has been adjusted to the second interval D.

In the above-described example, the present invention has been described based on the case where the index robot 120 and the carrier robot 320 approach the buffer unit 200 as an example. However, the present invention is not limited thereto. When an interval between a plurality of adjacent hands provided to one transfer robot approaching the buffer unit and an interval between a plurality of adjacent hands provided to another transfer robot approaching the buffer unit are different from each other, this may also be applied to the buffer unit.

In addition, in the above example, the present invention has been described based on the case where two pairs of index hands 122 are provided, one pair consists of two index hands 122, and the interval between the respective pairs is provided differently from the first interval D1, and one pair enters the buffer unit 220, and one pair transfers only the substrate W before being processed, and the other pair transfers only the substrate W after being processed as an example. However, the present invention is not limited thereto, and the interval of the two pairs may also be provided as the first interval D1. Accordingly, four index hands 122 may simultaneously enter the buffer unit 200. In addition, each index hand 122 may be provided to transfer the substrate W regardless of whether the substrate W is processed.

The above description may be equally applied to the transfer hand 322. In addition, in the above example, the present invention has been described based on the case where two pairs of transfer hands 322 are provided, one pair consists of two transfer hands 322, and the interval between the respective pairs is provided differently from the second interval D2, and one pair enters the buffer unit 220, and one pair transfers only the substrate W before being processed, and the other pair transfers only the substrate W after being processed as an example. However, the present invention is not limited thereto, and the interval of the two pairs may also be provided as the second interval D2. Accordingly, four transfer hands 322 may simultaneously enter the buffer unit 200. In addition, each transfer hand 322 may be provided to transfer the substrate W regardless of whether the substrate W is processed.

In addition, the present invention has been described based on the case where the liquid processing chamber 400 is provided to the processing module 30 as an example. However, the present invention is not limited thereto, and it is sufficient if a process chamber for processing the substrate W is provided, and it is not limited to the type of process for processing the substrate W.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

What is claimed is:

1. An apparatus for processing a substrate, the apparatus comprising:
an index module including a load port on which a container containing a substrate is placed and an index robot that loads or unloads a substrate into or from the container placed on the load port; and
a processing module for processing the substrate transferred from the container placed on the index module,
wherein the processing module includes:
a buffer unit on which the substrate is placed temporarily; and
a main transfer robot for transferring the substrate between the buffer unit and a processing chamber that processes the substrate,
the index robot is provided to approach the buffer unit, and
the buffer unit includes:
a plurality of buffers which is stacked on each other and supports the substrate; and
an interval changing unit for changing an interval between adjacent buffers among the buffers.

2. The apparatus of claim 1, wherein the interval changing unit includes:
a body having a plurality of support surfaces; and
a driver for moving the body in a vertical direction,
the plurality of support surfaces is provided to correspond to the plurality of buffers, respectively, and
when the body is moved upward, one of the plurality of buffers is moved upward by a corresponding support surface among the plurality of support surfaces.

3. The apparatus of claim 2, wherein each of the buffers has a groove penetrating in a vertical direction, and
the body is provided to be moved along the groove.

4. The apparatus of claim 2, wherein the plurality of support surfaces is provided to be stepped from each other such that the lower the plurality of support surfaces is positioned lower, the farther the plurality of support surfaces is from a center of the body,
each of the plurality of buffers has a contact surface that is in contact with a corresponding support surface among the plurality of support surfaces,
the contact surface is provided such that the higher the contact surface is positioned, the closer the contact surface is to a central axis of the body, and
the support surface and the contact surface that correspond to each other are provided such that the contact surface is positioned above the support surface.

5. The apparatus of claim 4, wherein a height difference between the support surfaces that are adjacent to each other among the plurality of support surfaces is provided to be greater than a height difference between the contact surfaces that are adjacent to each other among the plurality of contact surfaces.

6. The apparatus of claim 5, wherein the buffer unit is position-changeable between a first state in which an interval between the adjacent buffers is maintained at a first interval and a second state in which an interval between the adjacent buffers is maintained at a second interval that is greater than the first interval, and
when the body is disposed at a first height, the plurality of buffers is maintained in the first state, and when the body is at a second height higher than the first height, the plurality of buffers is maintained in the second state.

7. The apparatus of claim 6, wherein when the plurality of buffers is in the first state and the body is at the first height, a gap between the support surface and the contact surface that correspond to each other among the plurality of support surfaces and the plurality of contact surfaces is provided to be larger as the support surface and the contact surface are positioned lower.

8. The apparatus of claim 7, wherein as the body is moved from the first height to the second height, the contact surface positioned above among the plurality of contact surfaces first comes into contact with the corresponding support surface among the plurality of support surfaces and moves.

9. The apparatus of claim 8, wherein the index robot includes a plurality of index hands stacked on each other,
intervals between at least some of the plurality of index hands in the vertical direction are provided as a first interval,
the main transfer robot includes a plurality of transfer hands stacked on each other, and
intervals between at least some of the plurality of transfer hands in the vertical direction are provided as a second interval.

10. The apparatus of claim 9, wherein the buffer positioned at the lowest among the plurality of buffers is provided as a fixed buffer of which a position is fixed, and
the remaining buffers are provided as moving buffers of which positions are moved by the driver.

11. The apparatus of claim 10, wherein each of the buffers includes:
a body; and
a support having a shape that protrudes and extends inward from the body, and supports a lower surface of the substrate, and
the contact surface is provided to the body.

12. The apparatus of claim 9, further comprising:
a controller,
wherein the controller controls an interval changing unit to change the interval between adjacent buffers among the plurality of buffers to the first interval when the first robot approaches the buffer unit.

13. The apparatus of claim 12, wherein the controller controls the interval changing unit to change the interval between adjacent buffers among the plurality of buffers to the second interval when the second robot approaches the buffer unit.

14. An apparatus for transferring a substrate, the apparatus comprising:
a first robot having a plurality of first hands on which a substrate is placed and which is provided to be spaced apart from each other in a vertical direction;
a second robot having a plurality of second hands on which a substrate is placed and which is provided to be spaced apart from each other in the vertical direction; and
a buffer unit having a plurality of buffers on which the substrate is placed and which is stacked in the vertical direction,
each of the first robot and the second robot is provided to approach the buffer unit,
at least some of the plurality of first hands are provided to have a first interval in the vertical direction,
at least some of the plurality of second hands are provided to have a second interval in the vertical direction, and
the buffer unit further includes an interval changing unit for changing an interval between adjacent buffers among the plurality of buffers between the first interval and the second interval.

15. The apparatus of claim 14, wherein the interval changing unit includes:
a body having a plurality of support surfaces; and
a driver for moving the body between a first height and a second height higher than the first height,
the buffers are provided in three or more, and
all intervals between the adjacent buffers are provided to be changeable by a lifting movement of the body.

16. The apparatus of claim 15, wherein when the body is at the first height, an interval between adjacent buffers among the plurality of buffers is the first interval, and
when the body is at the second height, an interval between adjacent buffers among the plurality of buffers is the second interval.

17. The apparatus of claim 16, wherein when the body rises from the first height to the second height, the buffer is lifted from the buffer at the highest position among the plurality of buffers.

18. An apparatus for processing a substrate, the apparatus comprising:
an index module including a load port on which a container containing a substrate is placed and an index robot that loads or unloads a substrate into or from the container placed on the load port; and
a processing module for processing the substrate transferred from the container placed on the index module,
wherein the processing module includes:
a buffer unit on which the substrate is placed temporarily; and
a main transfer robot for transferring the substrate between the buffer unit and a processing chamber that processes the substrate,
the index robot is provided to approach the buffer unit, and
the buffer unit is position-changeable between a first state in which an interval between the adjacent buffers is maintained at a first interval and a second state in which an interval between the adjacent buffers is maintained at a second interval that is greater than the first interval,
the buffer unit includes:
a plurality of buffers that is stacked on each other and supports the substrate; and
an interval changing unit for changing an interval between the adjacent buffers among the buffers,
the interval changing unit includes:
a body having a plurality of support surfaces; and
a driver for moving the body in a vertical direction,
the plurality of support surfaces is provided to correspond to the plurality of buffers, respectively, and
the plurality of support surfaces is provided to be stepped from each other such that the lower the plurality of support surfaces is positioned, the farther the plurality of support surfaces is from a center of the body,
each of the plurality of buffers has a contact surface that is in contact with a corresponding support surface among the plurality of support surfaces,
the support surface and the contact surface that correspond to each other are provided such that the contact surface is positioned above the support surface,
the plurality of contact surfaces is provided such that the higher the contact surface is positioned, the closer the contact surface is to a central axis of the body,
a height difference between the support surfaces adjacent to each other among the plurality of support surfaces is provided to be greater than a height difference between the contact surfaces adjacent to each other among the plurality of contact surfaces,
the driver is provided to be able to move the body vertically between a first height and a second height higher than the first height,
the first height is a height at which an interval between the adjacent buffers is the first interval,
the second height is a height at which an interval between the adjacent buffers is the second interval when the support surface and the contact surface that correspond to each other are in contact with each other,
the index robot includes a plurality of index hands stacked on each other,
intervals between at least some of the plurality of index hands in a vertical direction is provided as the first interval,
the main transfer robot includes a plurality of transfer hands stacked on each other, and
intervals between at least some of the plurality of transfer hands in the vertical direction are provided as the second interval.

19. The apparatus of claim 18, further comprising:
a controller,
the controller controls the interval changing unit so that the buffer unit is changed to the first state when the index robot approaches the buffer unit, and
controls the interval changing unit so that the buffer unit is changed to the second state when the main transfer robot approaches the buffer unit.

20. The apparatus of claim 19, wherein the interval changing unit further includes a body guide that guides vertical movement of the body, and
the buffer unit further includes a buffer guide that has a longitudinal direction in the vertical direction and guides vertical movement of the plurality of buffers.
